(19) United States
(12) Patent Application Publication
(10) Pub. No.: US 2024/0332070 A1
(43) Pub. Date: Oct. 3, 2024

(54) ETCH STOP LAYER FOR INTERCONNECT STRUCTURES

(71) Applicant: Taiwan Semiconductor Manufacturing Company, Ltd., Hsinchu (TW)

(72) Inventors: Yen Ju Wu, Hsinchu (TW); Kai-Fang Cheng, Taoyuan City (TW); Cheng-Chin Lee, Taipei City (TW); Hsiao-Kang Chang, Hsinchu City (TW); Hsin-Yen Huang, New Taipei City (TW)

(21) Appl. No.: 18/349,672

(22) Filed: Jul. 10, 2023

Related U.S. Application Data
(60) Provisional application No. 63/492,944, filed on Mar. 29, 2023.

(51) Int. Cl. H01L 21/768; C23C 16/455; H01L 23/532

(52) U.S. Cl. CPC H01L 21/76832; C23C 16/45553; H01L 21/76802; H01L 21/7682; H01L 21/76879; H01L 23/53238

(57) ABSTRACT

A method according to the present disclosure includes receiving a workpiece that includes a first conductive feature embedded in a first dielectric layer, selectively depositing a capping layer over the first conductive feature, depositing a first etch stop layer (ESL) over the capping layer, depositing a glue layer over the first ESL, depositing a second ESL over the glue layer, depositing a second dielectric layer over the second ESL, forming an opening through the second dielectric layer, the second ESL, the glue layer, and the first ESL to expose the capping layer, and forming a second conductive feature in the opening. A density of the second ESL is greater than a density of the first ESL.

### PRIORITY DATA

The present application claims the benefit of U.S. Provisional Application No. 63/492,944, filed Mar. 29, 2023, the entirety of which is herein incorporated by reference.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

As device dimensions continue to shrink, back-end-of-line interconnect structures may account for more than one half of the parasitic capacitance of an IC chip, which may translate into more than 50% of dynamic power loss. For patterning purposes, an interconnect structure includes various dielectric layers of different properties. There is a need to lower dynamic power loss attributed to different dielectric layers in the interconnect structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of a method forming a contact structure, according to one or more aspects of the present disclosure.

FIGS. 2-14 are fragmentary cross-sectional views of a workpiece at various stages of fabrication according to the method in FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

As device dimensions continue to shrink, the industry works hard to keep up with Moore's Law. When the front-end-of-line (FEOL) devices becomes smaller, the back-end-of-line (BEOL) interconnect structures play a greater role in keep the switching speed up and power consumption down. For example, the BEOL interconnect structures may include dielectric layers of low dielectric constants to keep the parasitic capacitance down. In order to achieve etch end point detection, etch stop layers (ESLs) that are more etch resistant may be implemented to provide different etch rates. However, a greater etch resistance usually comes with a greater dielectric constant. As a result, implementation of etch stop layers may cause increase of the parasitic capacitance. This dilemma has posted a challenge to reduce the dielectric constant of the ESLs. Additionally, it is desirable to have etch stop layers with moisture blocking properties. Oxygen-containing etch stop layers formed using carbon dioxide plasma may provide satisfactory moisture block capability. However, use of carbon dioxide plasma may lead to oxidation concerns.

The present disclosure provides a method to form an etch stop layer (ESL) structure that includes a low density, low-dielectric-constant dielectric layer that is glued to a high density dielectric layer by a glue layer. The low density, low-dielectric-constant dielectric layer helps reduce parasitic capacitance. The high density dielectric layer serves as a hermetic moisture barrier. The glue layer improves the adhesion of the low density, low-dielectric-constant dielectric layer and the high density dielectric layer.

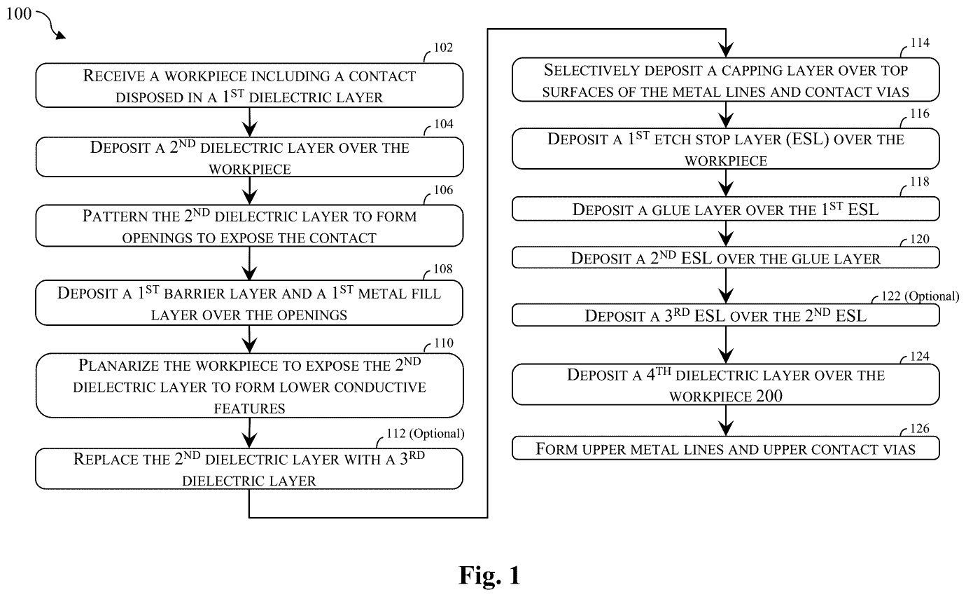

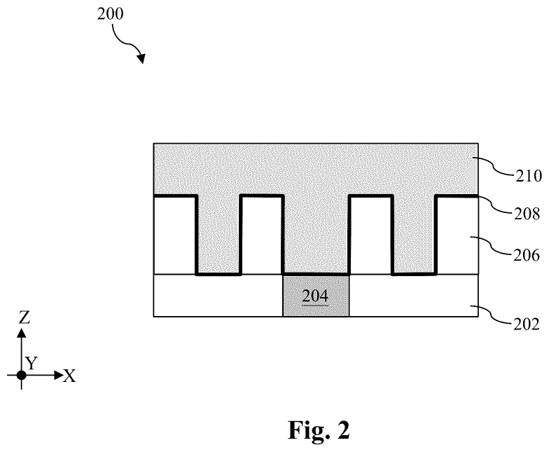

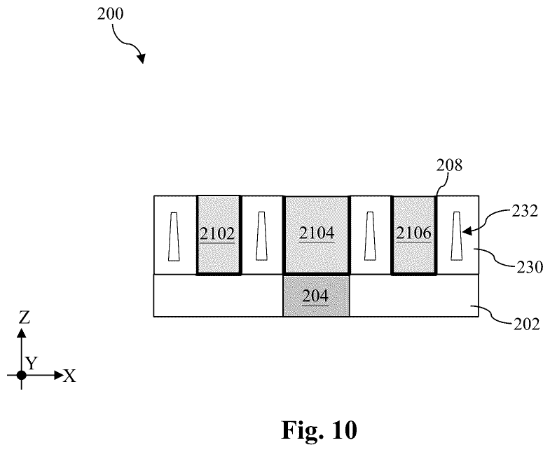

The various aspects of the present disclosure will now be described in more detail with reference to the figures. In that regard, FIG. 1 is a flowchart illustrating method 100 for forming a contact structure on a workpiece 200. Method 100 is merely an example and is not intended to limit the present disclosure to what is explicitly illustrated in method 100. Additional steps may be provided before, during and after method 100, and some steps described can be replaced, eliminated, or moved around for additional embodiments of the method. Not all steps are described herein in detail for reasons of simplicity. Method 100 is described below in conjunction with FIGS. 2-14, which are fragmentary cross-sectional views of a workpiece 200 at different stages of fabrication according to embodiments of method 100. Because the workpiece 200 will be fabricated into a semiconductor structure 200 upon conclusion of the fabrication processes, the workpiece 200 may be referred to as a semiconductor structure 200 as the context requires. Additionally, throughout the present application and across different embodiments, like reference numerals denote like features with similar structures and compositions, unless otherwise excepted. Source/drain region(s) may refer to a source or a drain, individually or collectively, dependent upon the context.

Referring to FIGS. 1 and 2, method 100 includes a block 102 where a workpiece 200 that includes a contact 204 disposed in a first dielectric layer 202 is received. The contact 204 includes copper (Cu), cobalt (Co), nickel (Ni), ruthenium (Ru), or tungsten (W) and may be a metal line, a contact via, or a source/drain contact. The first dielectric layer 202 may be an interlayer dielectric (ILD) layer or an intermetal dielectric (IMD) layer. In some embodiments, the first dielectric layer 202 may include silicon oxide or a low-k dielectric material with a k-value (dielectric constant) smaller than that of silicon oxide, which is about 3.9. In some embodiments, the low-k dielectric material includes a porous organosilicate thin film (e.g., SiOCH), tetraethylorthosilicate (TEOS) oxide, un-doped silicate glass, borophosphosilicate glass (BPSG), fluorosilicate glass (FSG), phosphosilicate glass (PSG), fluorine-doped silicon dioxide, carbon-doped silicon dioxide, porous silicon dioxide, porous carbon-doped silicon dioxide, silicon oxycarbonitride (SiOCN), spin-on silicon based polymeric dielectrics, or combinations thereof. While not explicitly illustrated in the figures, the contact 204 may be spaced apart from the first dielectric layer 202 by a barrier layer. The barrier layer may include titanium nitride, cobalt nitride, manganese nitride, nickel nitride, tungsten nitride, or tantalum nitride.

Referring to FIGS. 1 and 2, method 100 includes a block 104 where a second dielectric layer 206 is deposited over the workpiece 200. In some embodiments, a composition of the second dielectric layer 206 may be similar to that of the first dielectric layer 202. In some implementations, the second dielectric layer 206 may be deposited over the contact 204 and the first dielectric layer 202 using spin-on coating, chemical vapor deposition (CVD), or flowable chemical vapor deposition (FCVD). In some instances, in order to improve the quality and density of the second dielectric layer 206 to withstand the subsequent patterning operations, an anneal process may be performed to improve the quality of the second dielectric layer 206. After deposition of the second dielectric layer 206, a planarization process, such as a chemical mechanical polishing (CMP) process may be performed to the second dielectric layer 206 to provide a planar top surface.

Referring to FIGS. 1 and 2, method 100 includes a block 106 where the second dielectric layer 206 is patterned to form openings. Referring to FIG. 2, the second dielectric layer 206 may be patterned using a combination of photolithography processes and etch processes. In an example process, a hard mask may be deposited over the second dielectric layer 206 and a resist layer may be deposited over hard mask. The resist layer may be a single layer or a multi-layer. To pattern the resist layer, the resist layer is exposed to a radiation reflected from or transmitting through a photomask, baked in a post-exposure bake process, developed in a development process, and rinsed. The pattern of the photomask is thereby transferred to the resist layer. The patterned resist layer is applied as an etch mask to etch the hard mask, thereby forming a patterned hard mask. The patterned hard mask is then used as an etch mask to pattern the underlying second dielectric layer 206. In some embodiments, the etching at block 106 may be a dry etch process. For example, the dry etch process may implement an oxygen-containing gas, hydrogen, a fluorine-containing gas (e.g., CF₄, SF₆, CH₂F₂, CHF₃, CH₃F, C₄H₈, C₄F₆, and/or C₂F₆), a carbon-containing gas (e.g., CO, CH₄, and/or C₃H₈), a chlorine-containing gas (e.g., Cl₂, CHCl₃, CCl₄, and/or BCl₃), a bromine-containing gas (e.g., HBr and/or CHBR₃), an iodine-containing gas, other suitable gases and/or plasmas, and/or combinations thereof. As shown in FIG. 2, at least one of the openings reaches and exposes a top surface of the contact 204.

Referring to FIGS. 1 and 2, method 100 includes a block 108 where a first barrier layer 208 and a first metal fill layer 210 are deposited over the openings. In some embodiments, the first barrier layer 208 includes a metal nitride, such as titanium nitride, cobalt nitride, manganese nitride, nickel nitride, tungsten nitride, or tantalum nitride. In one embodiment, the first barrier layer 208 includes tantalum nitride. While tantalum nitride is less electrically conductive than some of the other metal nitrides, it has a better barrier property, which allows it to have a smaller thickness and still effectively function as a barrier layer. The first barrier layer 208 may be deposited using chemical vapor deposition (CVD), plasma-enhanced CVD (PECVD), atomic layer deposition (ALD), or plasma-enhanced ALD (PEALD). Precursors used to deposit the first barrier layer 208 may include a metal-containing metalorganic precursor and nitrogen-containing precursor. For example, when the first barrier layer 208 includes tantalum nitride, precursors used may include pentakis(dimethylamino)tantalum (PDMAT) or t-butylimino-tris(dimethylamino)tantalum (TBTDMT), as the metal-containing metalorganic precursor and ammonia or monomethylhydrazine (MMH) as the nitrogen-containing precursor. The metal fill layer 210 may include copper (Cu), cobalt (Co), nickel (Ni), ruthenium (Ru), or tungsten (W). In one embodiment, the metal fill layer 210 includes copper (Cu). The metal fill layer 210 may be deposited using PVD, electroplating, or electroless plating. As an example, the metal fill layer 210 may be deposited using electroplating. In this example process, a seed layer may be deposited over the workpiece 200 using PVD or CVD. The seed layer may include titanium, copper, or both. Then copper is deposited over the seed layer using electroplating.

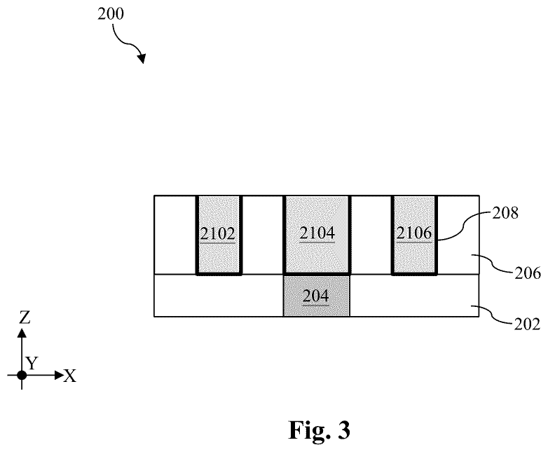

Referring to FIGS. 1 and 3, method 100 includes a block 110 where the workpiece 200 is planarized to expose the second dielectric layer 206 to form lower conductive features 2102, 2104 and 2106. The planarization at block 110 may include chemical mechanical polishing (CMP). As shown in FIG. 3, the workpiece 200 is planarized until a planar top surface of the workpiece 200 includes top surfaces of the second dielectric layer 206, the first barrier layer 208, and the metal fill layer 210. In the fragmentary cross-sectional view shown in FIG. 3, the planarization forms a first lower conductive feature 2102, a second lower conductive feature 2104, and a third lower conductive feature 2106. The first, second and third lower conductive features 2102, 2104, and 2106 may include metal lines, contact vias or both. In the embodiments represented in FIG. 3, the second lower conductive feature 2104 physically and electrically couples to the contact 204.

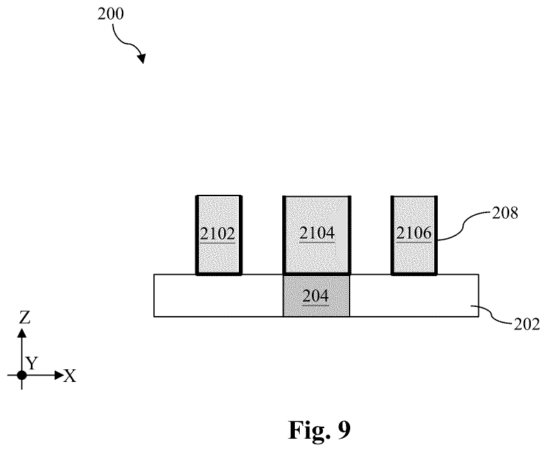

Referring to FIGS. 1, 9 and 10, method 100 may optionally include a block 112 where the second dielectric layer 206 is replaced with a third dielectric layer 230. In some embodiments, the second dielectric layer 206 is removed and replaced with a dielectric structure that has a lower dielectric constant. In the embodiment represented in FIG. 9, the second dielectric layer 206 may be selectively removed using a selective wet etching process. For example, when the second dielectric layer 206 includes silicon oxide, the selective wet etching process may include use of ammonium fluoride (NH₄F) and hydrofluoric acid (HF). After the selective removal of the second dielectric layer 206, a third dielectric layer 230 may be deposited using CVD. Because deposition of the third dielectric layer 230 may merge over the openings left vacant by the removal of the second dielectric layer 206, air gaps 232 (or voids 232) may be formed in the third dielectric layer 230. The presence of the air gaps 232 helps reduce the overall dielectric constant of the third dielectric layer 230 even when a composition of the third dielectric layer 230 is the same as a composition of the second dielectric layer 206. In some embodiments, the third dielectric layer 230 may include silicon oxide or silicon oxycarbonitride.

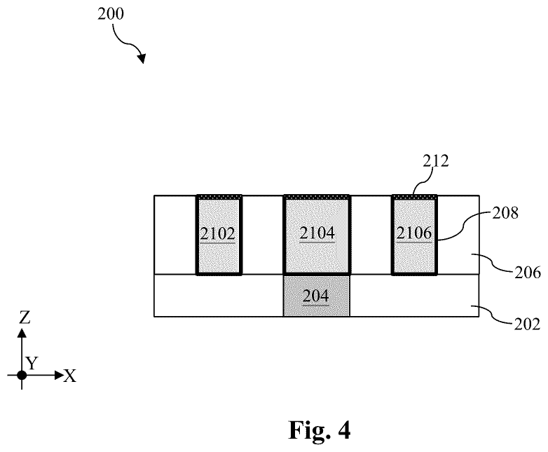

Referring to FIGS. 1 and 4, method 100 includes a block 114 where a capping layer 212 is selectively deposited over top surfaces of the lower conductive features 2102, 2104 and 2106. The capping layer 212 may also be referred to as a metal cap 212 or a conductive cap layer 212 and is formed from a metal different from the metal that forms the conductive features (including the first lower conductive feature 2102, the second lower conductive feature 2104, and the third lower conductive feature 2106). In embodiments where the lower conductive features 2102, 2104 and 2106 are formed of copper, the capping layer 212 may include titanium (Ti), tantalum (Ta), molybdenum (Mo), nickel (Ni), cobalt (Co), ruthenium (Ru), or other refractory metals. In the depicted embodiment, the capping layer 212 includes cobalt (Co). In some implementations, the capping layer 212 is selectively deposited on top surfaces of the first lower conductive feature 2102, the second lower conductive feature 2104, and the third lower conductive feature 2106 by CVD using metalorganic precursors each having a metal ion and coordinating ligands. An example cobalt metalorganic precursor may be cyclopentadienylcobalt dicarbonyl ((C₅H₅)Co(CO)₂. As shown in FIG. 4, due to the selective nature of formation, the capping layer 212 is only deposited on the lower conductive features 2102, 2104 and 2106 and is absent from the surfaces of the second dielectric layer 206. When the second dielectric layer 206 is replaced with the third dielectric layer 230 when operations at block 112 are performed. Besides serving as a diffusion barrier, the capping layer 212 may also repair damages done to the lower conductive features 2102, 2104 and 2106 during the planarization process. In some alternative embodiments, the capping layer 212 may include graphene.

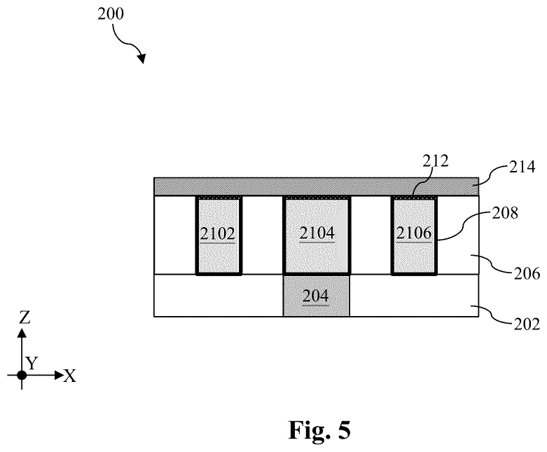

Referring to FIGS. 1 and 5, method 100 includes a block 116 where the first etch stop layer (ESL) 214 is deposited over the workpiece 200. The first ESL 214 includes an oxygen-free dielectric material. In some embodiments, the first ESL 214 includes a low-k dielectric material such as silicon carbonitride (SiCN) and may be deposited using CVD, atomic layer deposition (ALD), plasma-enhanced CVD (PECVD), plasma-enhanced ALD (PEALD). Precursors used to deposit the first ESL 214 may include a first precursor that includes silicon and carbon and a second precursor that includes nitrogen. An example of the first precursor includes tetramethyl silane (Si(CH₃)₄) and an example of the second precursor includes ammonia (NH₃). Because the first ESL 214 is free of oxygen atoms, its deposition process does not involve use of plasma of carbon dioxide (CO₂), thereby reducing oxidation concerns. In some implementations, the first ESL 214 includes about 30% to 60% of silicon (Si), about 25% to 60% of carbon (C), and about 10%-20% nitrogen (N). In some embodiments, a dielectric constant of the first ESL 214 is between about 3.5 and about 4.5. When the dielectric constant of the first ESL 214 is lower than 3.5, the first ESL 214 may not possess the etch resistant property necessary to serve as an etch stop layer. When the dielectric constant of the first ESL 214 is greater than 4.5, its contribution for capacitance reduction is negligible. In some instances, a thickness of the first ESL 214 may be between about 35 Å and about 55 Å. When the first ESL 214 is thicker than 55Å, the overall thickness of the ESLs may be too high to impact the device dimension. When the first ESL 214 is thinner than 35 Å, the first ESL 214 may not contribute to capacitance reduction enough to justify the added process steps. The fact that the first ESL 214 is free of oxygen atom may be contrary to some conventional wisdom. In some technology, the similarly situated etch stop layer may include silicon oxycarbide or oxygen-doped silicon carbide because oxygen treatments, such as carbon dioxide plasma treatments, have been shown to increase density and moisture blocking ability of the etch stop layer. It is noted that while the first ESL 214 is thinner than the second ESL 218 (to be described below) as the former is serving as a moisture block layer, the first ESL 214 is on top of the metal line and contributes more to the total capacitance. Simulation results and experiments show that, by lowering the dielectric constant of the first ESL 214, the total capacitance can be effectively reduced

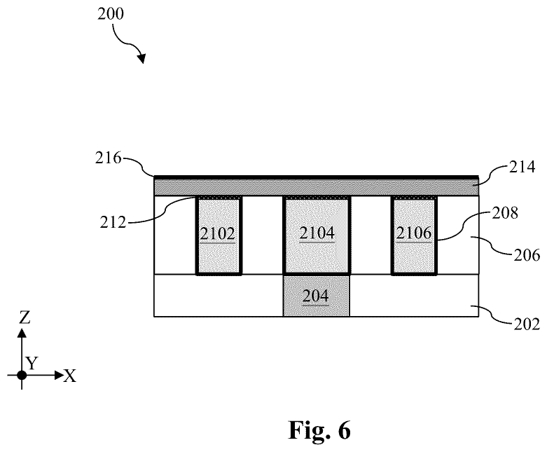

Referring to FIGS. 1 and 6, method 100 includes a block 118 where a glue layer 216 is deposited over the first ESL 214. The glue layer 216 may be aluminum nitride (AlN) or a silicon-rich material. When the glue layer 216 includes aluminum nitride (AlN), the glue layer 216 may be deposited using multiple thermal ALD cycles at a temperature between about 300° C. and about 400° C. and its deposition may include use of an aluminum-containing precursor, such as trimethylaluminum (Al(CH₃)₃) and a nitrogen-containing precursor, such as ammonia (NH₃). When the glue layer 216 includes silicon-rich material, it may be deposited by CVD using a silicon-containing precursor (such as silane (SiH₄)) and a nitrogen-containing precursor (such as ammonia (NH₃)). When the glue layer 216 includes silicon-rich material, it may be deposited in the same chamber where the first ESL 214 and the second ESL 218 (to be described below) are deposited and the deposition of the first ESL 214, the glue layer 216, and the second ESL 218 When the glue layer 216 includes AN, it may not be deposited in the same chamber where the first ESL 214 and the second ESL 218 are deposited. The glue layer 216 functions to improve the adhesion between the first ESL 214 and a second ESL 218 (to be described below). Experiments have shown that two separately formed oxygen-free dielectric layers (such as the first ESL 214 and the second ESL 218 here) may adhere poorly together, compromising their moisture blocking ability. For example, experimental results have shown that, when no glue layer is formed to boost adhesion, a hermetic silicon carbonitride layer may adhere so poorly to a low-k silicon carbonitride layer that they, as a whole, fail moisture blocking tests. Because the glue layer 216 only functions to improve adhesion, a thickness of the glue layer 216 is substantially smaller than that of the first ESL 214 or the second ESL 218. In some implementations, the thickness of the glue layer 216 may be between about 3 Å and about 10 Å. When the glue layer 216 is thinner than 3 Å, such a thickness is not sufficient to improve adhesion. Because a dielectric constant of the glue layer 216 is greater than that of the first ESL 214 or the second ESL 218, when the glue layer 216 is thicker than 10 Å, it may defeat the purpose of reducing capacitance. For example, when the glue layer 216 includes aluminum nitride, its dielectric constant is about 8.9 which is a lot higher than that of the first ESL 214 or the second ESL 218.

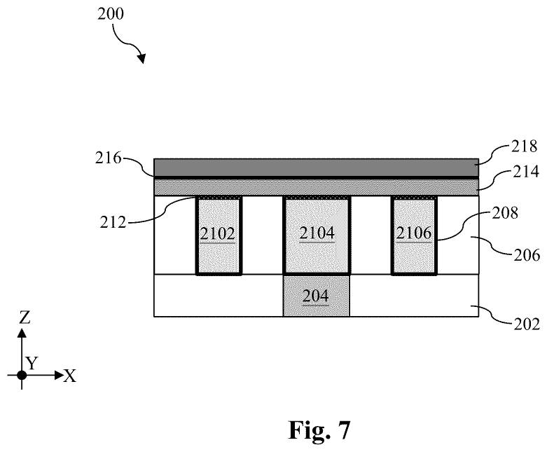

Referring to FIGS. 1 and 7, method 100 includes a block 120 where a second ESL 218 is deposited over the glue layer 216. The second ESL 218 includes an oxygen-free dielectric material. In some embodiments, the second ESL 218 may also include silicon carbonitride (SiCN) and is deposited in a way such that it can serve as a hermetic layer to block moisture ingression. While the second ESL 218 may be similar to the first ESL 214 in terms of composition, the second ESL 218 is deposited with help of low frequency plasma, with a frequency between about 200K Hz and about 600 K Hz. For comparison purposes, high frequency plasma may have a frequency between about 10M Hz and about 20M Hz. For example, the nitrogen-containing precursor may be supplied during high frequency pulses and low frequency pulses when depositing the second ESL 218 but the nitrogen-containing precursor may only be supplied during high frequency pulses when depositing the first ESL 214. The low frequency plasma enhances ion bombardment during the deposition of the second ESL 218, thereby densifying the second ESL 218. For avoidance of doubts, the low frequency plasma is not used when the first ESL 214 is deposited. As a result, a density of the second ESL 218 is greater than a density of the first ESL 214. In some embodiments, the density of the first ESL 214 may be between about 1.5 g/cm³ and about 1.8 g/cm³ and the density of the second ESL 218 may be between about 1.8 g/cm³ and about 2.0 g/cm³. The denser second ESL 218 has a dielectric constant greater than that of the first ESL 214. In some embodiments, a dielectric constant of the second ESL 218 may be between about 4.5 and about 5.5. To achieve satisfactory moisture blocking effect, the second ESL 218 may be thicker than the first ESL 214. In some implementations, the second ESL 218 has a thickness between about 40 Å and about 100 Å.

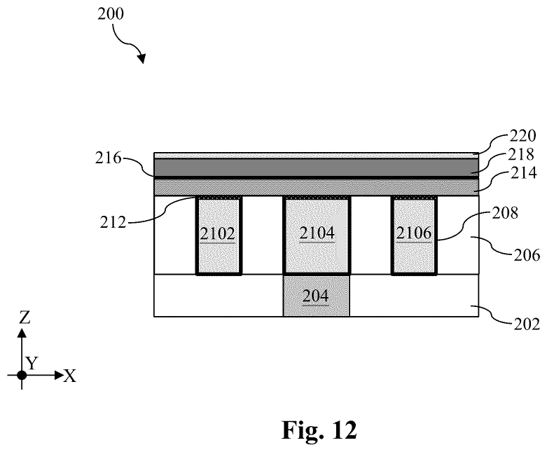

Referring to FIGS. 1 and 12, method 100 may optionally include a block 122 where a third ESL 220 is deposited over the second ESL 218. The third ESL 220 includes a metal oxide. In some embodiments, the third ESL 220 may include aluminum oxide. At block 122, the third ESL 220 may be deposited using CVD, ALD, PECVD, or PEALD. Compared to the first ESL 214 and the second ESL 218, the third ESL 220 has a greater dielectric constant and higher etch resistance. For example, when the third ESL 220 includes aluminum oxide, the dielectric constant of the third ESL 220 may be between about 9 and about 10, which is about or more than two of that of the first ESL 214 or the second ESL 218. The third ESL 220, when implemented, provides better control of critical dimensions (CD). To reduce the dielectric constant impact of the third ESL 220, a thickness of the third ESL 220 may be smaller than that of the first ESL 214 or the second ESL 218. In some embodiments, when the third ESL 220 is implemented, the third ESL 220 may have a thickness between about 3 Å and about 50 Å.

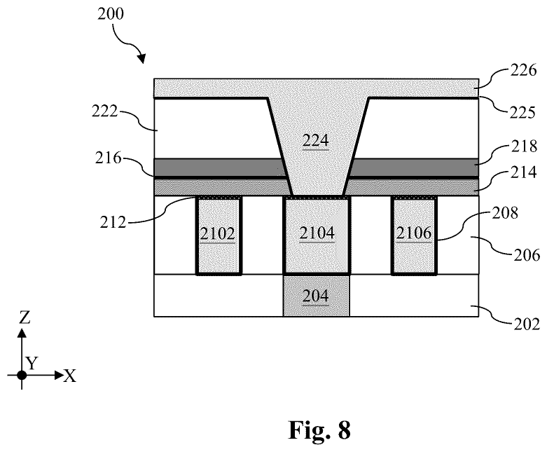

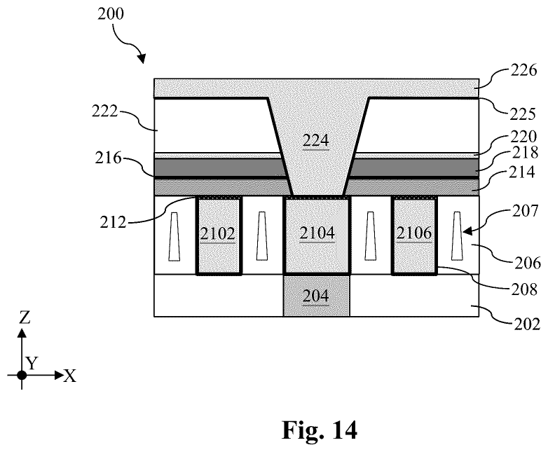

Referring to FIGS. 1, 8, 11, 13, and 14, method 100 includes a block 124 where a fourth dielectric layer 222 is deposited over the workpiece 200. After the deposition of the second ESL 218 (or after the optional deposition of the third ESL 220), the fourth dielectric layer 222 is deposited over the workpiece 200. In some embodiments, the fourth dielectric layer 222 may include silicon oxide or a low-k dielectric material with a k-value (dielectric constant) smaller than that of silicon oxide, which is about 3.9. In some embodiments, the low-k dielectric material includes a porous organosilicate thin film (e.g., SiOCH), tetraethylorthosilicate (TEOS) oxide, un-doped silicate glass, borophosphosilicate glass (BPSG), fluorosilicate glass (FSG), phosphosilicate glass (PSG), fluorine-doped silicon dioxide, carbon-doped silicon dioxide, porous silicon dioxide, porous carbon-doped silicon dioxide, silicon oxycarbonitride (SiOCN), spin-on silicon based polymeric dielectrics, or combinations thereof. In embodiments illustrated in FIGS. 8, 11 and 13, the fourth dielectric layer 222 is deposited over and in contact with the second ESL 218. In other embodiments illustrated in FIG. 14, when the third ESL 220 is implemented, the fourth dielectric layer 222 is deposited over and in contact with the third ESL 220.

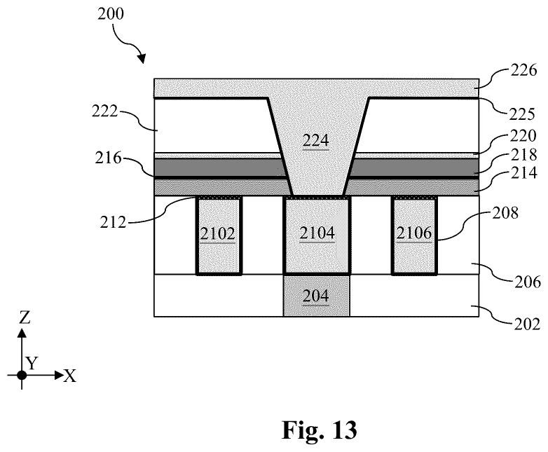

Referring to FIGS. 1, 8, 11, 13, and 14, method 100 includes a block 126 where upper metal lines 226 and metal contact vias 224 are formed. At block 126, at least one upper opening is formed through the fourth dielectric layer 222, the third ESL 220 (shown in FIG. 13, when the third ESL 220 is implemented), the second ESL 218, the glue layer 216, and the first ESL 214 to expose the capping layer 212 of at least one of the lower conductive features. In the embodiment represented in FIGS. 8, 11, 13, and 14, the opening exposes the capping layer 212 on the second lower conductive feature 2104. The fourth dielectric layer 222 may be patterned using a combination of photolithography processes and etch processes. In an example process, a hard mask may be deposited over the fourth dielectric layer 222 and a resist layer may be deposited over hard mask. The resist layer may be a single layer or a multi-layer. To pattern the resist layer, the resist layer is exposed to a radiation reflected from or transmitting through a photomask, baked in a post-exposure bake process, developed in a development process, and rinsed. The pattern of the photomask is thereby transferred to the resist layer. The patterned resist layer is applied as an etch mask to etch the hard mask, thereby forming a patterned hard mask. The patterned hard mask is then used as an etch mask to pattern the underlying fourth dielectric layer 222. In some embodiments, the etching at block 106 may be a dry etch process. For example, the dry etch process may implement an oxygen-containing gas, hydrogen, a fluorine-containing gas (e.g., CF₄, SF₆, CH₂F₂, CHF₃, CH₃F, C₄H₈, C₄F₆, and/or C₂F₆), a carbon-containing gas (e.g., CO, CH₄, and/or C₃H₈), a chlorine-containing gas (e.g., Cl₂, CHCl₃, CCl₄, and/or BCl₃), a bromine-containing gas (e.g., HBr and/or CHBR₃), an iodine-containing gas, other suitable gases and/or plasmas, and/or combinations thereof. As shown in FIGS. 8, 11, 13, and 14, at least one of the upper openings reaches and exposes the capping layer 212 over the second lower conductive feature 2104.

After the opening is formed in the fourth dielectric layer 222, a second barrier layer 225 may be deposited over the workpiece 200, including over the sidewalls of the opening and a top surface of the fourth dielectric layer 222. In some embodiments, the second barrier layer 225 includes a metal nitride, such as titanium nitride, cobalt nitride, manganese nitride, nickel nitride, tungsten nitride, or tantalum nitride. In one embodiment, the second barrier layer 225 includes tantalum nitride. While tantalum nitride is less electrically conductive than some of the other metal nitrides, it has a better barrier property, which allows it to have a smaller thickness and still effectively function as a barrier layer. The second barrier layer 225 may be deposited using chemical vapor deposition (CVD), plasma-enhanced CVD (PECVD), atomic layer deposition (ALD), or plasma-enhanced ALD (PEALD). Precursors used to deposit the second barrier layer 225 may include a metal-containing metalorganic precursor and nitrogen-containing precursor. For example, when the second barrier layer 225 includes tantalum nitride, precursors used may include pentakis(dimethylamino)tantalum (PDMAT) or t-butylimino-tris(dimethylamino)tantalum (TBTDMT), as the metal-containing metalorganic precursor and ammonia or monomethylhydrazine (MMH) as the nitrogen-containing precursor.

After the deposition of the second barrier layer 225, a metal fill layer is deposited over the second barrier layer 225 to form a metal contact via 224 disposed in the opening and an upper metal line 226 disposed over the metal contact via 224. The metal fill layer may include copper (Cu), cobalt (Co), nickel (Ni), ruthenium (Ru), or tungsten (W). In one embodiment, the metal fill layer includes copper (Cu). The metal fill layer may be deposited using PVD, electroplating, or electroless plating. As an example, at block 126, the metal fill layer may be deposited using electroplating. In this example process, a seed layer may be deposited over the workpiece 200 using PVD or CVD. The seed layer may include titanium, copper, or both. Then copper is deposited over the seed layer using electroplating.

Depending on whether the operational operations at blocks 112 and 122 are performed or not performed, each of FIGS. 8, 11, 13, and 14 shows a final semiconductor structure 200 fabricated using method 100 in FIG. 1. Referring to FIG. 8. each of the first lower conductive feature 2102, second lower conductive feature 2104, and the third lower conductive feature 2106 are embedded in and surrounded by the second dielectric layer 206. Each of the first lower conductive feature 2102, second lower conductive feature 2104, and the third lower conductive feature 2106 is capped by the capping layer 212, which may include cobalt (Co). The first ESL 214 is deposited over and in contact with the top surface of the second dielectric layer 206 and the capping layer 212 on each of the first lower conductive feature 2102, second lower conductive feature 2104, and the third lower conductive feature 2106. The second ESL 218 is disposed over the first ESL 214. The glue layer 216 is sandwiched directly between the first ESL 214 and the second ESL 218 along the Z direction (i.e., vertical direction) to improve adhesion between them. The improved adhesion is shown to increase the moisture blocking ability of the first ESL 214 and the second ESL 218. When the first ESL 214 and the second ESL 218 include silicon carbonitride, they may be collectively referred to as a silicon carbonitride bilayer. Out of the two, the first ESL 214 may be deposited without ion bombardment from low frequency ammonia plasma while the second ESL 218 may be deposited with ion bombardment from low frequency ammonia plasma. The result is that the second ESL 218 has a greater density and a greater dielectric constant that the first ESL 214. Simulation results show that the implementation of the silicon carbonitride bilayer (i.e., the first ESL 214 and the second ESL 218) may lead to between 4.5% and about 5.5% of capacitance reduction.

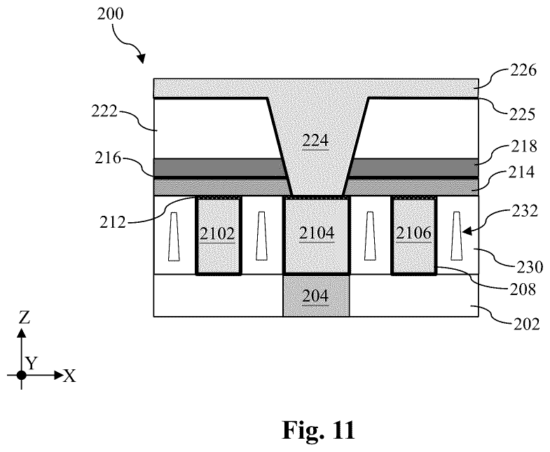

Compared to the semiconductor structure 200 in FIG. 8, the second dielectric layer 206 in the counterpart in FIG. 11 is replaced with the third dielectric layer 230. Due to the confined space among the first lower conductive feature 2102, second lower conductive feature 2104, and the third lower conductive feature 2106, the third dielectric layer 230 may prematurely merge over the openings, resulting in formation of the voids 232. Because the gas species in the voids 232 has a dielectric constant close to 1, the overall dielectric constant of the third dielectric layer 230 and the voids 232 is smaller than that of the second dielectric layer 206. The replacement of the second dielectric layer 206 with the third dielectric layer 230 may further reduce the parasitic capacitance of the semiconductor structure 200 in FIG. 11.

Compared to the semiconductor structure 200 in FIG. 8, the counterpart in FIG. 13 further includes the third ESL 220 disposed directly on the top surface of the second ESL 218. The third ESL 220 includes metal oxide, which is more etch-resistant than the second ESL 218. The third ESL 220 helps control the critical dimension when patterning the upper opening through the ESL layers.

Compared to the semiconductor structure 200 in FIG. 11, the counterpart in FIG. 14 further includes the third ESL 220 disposed directly on the top surface of the second ESL 218. The third ESL 220 includes metal oxide, which is more etch-resistant than the second ESL 218. The third ESL 220 helps control the critical dimension when patterning the upper opening through the ESL layers.

Thus, one of the embodiments of the present disclosure provides a method. The method includes receiving a workpiece including a first conductive feature embedded in a first dielectric layer, selectively depositing a capping layer over the first conductive feature, depositing a first etch stop layer (ESL) over the capping layer, depositing a glue layer over the first ESL, depositing a second ESL over the glue layer, depositing a second dielectric layer over the second ESL, forming an opening through the second dielectric layer, the second ESL, the glue layer, and the first ESL to expose the capping layer, and forming a second conductive feature in the opening. A density of the second ESL is greater than a density of the first ESL.

In some embodiments, the glue layer includes aluminum nitride or silicon nitride. In some implementations, the first ESL and the second ESL include silicon carbonitride. In some instances, a dielectric constant of the second ESL is greater than a dielectric constant of the first ESL. In some embodiments, the method further includes before the depositing of the second dielectric layer, depositing a third ESL over the second ESL. The third ESL includes aluminum oxide. In some embodiments. the method further includes after the selectively depositing of the capping layer, replacing the first dielectric layer with a third dielectric layer. In some embodiments, the third dielectric layer includes air gaps.

In another of the embodiments, a method is provided. The method includes receiving a workpiece including a first conductive feature embedded in a first dielectric layer, selectively depositing a capping layer over the first conductive feature, depositing a first etch stop layer (ESL) over the capping layer using a first plasma-enhanced chemical vapor deposition (PECVD) process, depositing a glue layer over the first ESL, depositing a second ESL over the glue layer using a second PECVD process, depositing a second dielectric layer over the second ESL, forming an opening through the second dielectric layer, the second ESL, the glue layer, and the first ESL to expose the capping layer, and forming a second conductive feature in the opening. Each of the first PECVD process and second PECVD process include high-frequency pulses and low-frequency pulses. In the first PECVD process, plasma of a nitrogen-containing precursor is introduced during the high-frequency pulses. In the second PECVD process, plasma of the nitrogen-containing precursor is introduced during both the high-frequency pulses and the low-frequency pulses.

In some embodiments, the first ESL and the second ESL include silicon carbonitride. In some implementations, a density of the second ESL is greater than a density of the first ESL. In some implementations, a dielectric constant of the second ESL is greater than a dielectric constant of the second ESL. In some instances, the capping layer includes cobalt or graphene. In some embodiments, the method further includes before the depositing of the second dielectric layer, depositing a third ESL over the second ESL. In some embodiments, the third ESL includes aluminum oxide. In some implementations, the capping layer includes aluminum nitride. In some instances, the selectively depositing the capping layer includes an atomic layer deposition (ALD) process that includes use of trimethylaluminum (Al(CH₃)₃) and ammonia (NH₃).

In yet another of the embodiments, a semiconductor structure is provided. The semiconductor structure includes a first conductive feature disposed in a first dielectric layer, a capping layer disposed on the first conductive feature, a first etch stop layer (ESL) disposed over and in contact with top surfaces of the capping layer and the first dielectric layer, a glue layer disposed on the first ESL, a second ESL disposed on the glue layer, a second dielectric layer over the second ESL, and a second conductive feature extending through the second dielectric layer, the second ESL, the glue layer, and the second ESL to contact the capping layer. A density of the second ESL is greater than a density of the first ESL.

In some embodiments, the glue layer includes aluminum nitride or silicon nitride. In some implementations, a dielectric constant of the second ESL is greater than a dielectric constant of the second ESL. In some instances, the first ESL and the second ESL include silicon carbonitride.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a workpiece comprising a first conductive feature embedded in a first dielectric layer;
selectively depositing a capping layer over the first conductive feature;
depositing a first etch stop layer (ESL) over the capping layer;
depositing a glue layer over the first ESL;
depositing a second ESL over the glue layer;
depositing a second dielectric layer over the second ESL;
forming an opening through the second dielectric layer, the second ESL, the glue layer, and the first ESL to expose the capping layer; and
forming a second conductive feature in the opening,
wherein a density of the second ESL is greater than a density of the first ESL.

2. The method of claim 1, wherein the glue layer comprises aluminum nitride or silicon nitride.

3. The method of claim 1, wherein the first ESL and the second ESL comprise silicon carbonitride.

4. The method of claim 1, wherein a dielectric constant of the second ESL is greater than a dielectric constant of the first ESL.

5. The method of claim 1, further comprising:
before the depositing of the second dielectric layer, depositing a third ESL over the second ESL,
wherein the third ESL comprises aluminum oxide.

6. The method of claim 1, further comprising:
after the selectively depositing of the capping layer, replacing the first dielectric layer with a third dielectric layer.

7. The method of claim 6, wherein the third dielectric layer comprises air gaps.

8. A method, comprising:
receiving a workpiece comprising a first conductive feature embedded in a first dielectric layer;
selectively depositing a capping layer over the first conductive feature;
depositing a first etch stop layer (ESL) over the capping layer using a first plasma-enhanced chemical vapor deposition (PECVD) process;
depositing a glue layer over the first ESL;
depositing a second ESL over the glue layer using a second PECVD process;
depositing a second dielectric layer over the second ESL;
forming an opening through the second dielectric layer, the second ESL, the glue layer, and the first ESL to expose the capping layer; and
forming a second conductive feature in the opening,
wherein each of the first PECVD process and second PECVD process comprise high-frequency pulses and low-frequency pulses,
wherein, in the first PECVD process, plasma of a nitrogen-containing precursor is introduced during the high-frequency pulses,
wherein, in the second PECVD process, plasma of the nitrogen-containing precursor is introduced during both the high-frequency pulses and the low-frequency pulses.

9. The method of claim 8, wherein the first ESL and the second ESL comprise silicon carbonitride.

10. The method of claim 8, wherein a density of the second ESL is greater than a density of the first ESL.

11. The method of claim 8, wherein a dielectric constant of the second ESL is greater than a dielectric constant of the second ESL.

12. The method of claim 8, wherein the capping layer comprises cobalt or graphene.

13. The method of claim 8, further comprising:
before the depositing of the second dielectric layer, depositing a third ESL over the second ESL.

14. The method of claim 13, wherein the third ESL comprises aluminum oxide.

15. The method of claim 8, wherein the capping layer comprises aluminum nitride.

16. The method of claim 15, wherein the selectively depositing the capping layer comprises an atomic layer deposition (ALD) process that includes use of trimethylaluminum (Al(CH₃)₃) and ammonia (NH₃).

17. A semiconductor structure, comprising:
a first conductive feature disposed in a first dielectric layer;
a capping layer disposed on the first conductive feature;
a first etch stop layer (ESL) disposed over and in contact with top surfaces of the capping layer and the first dielectric layer;
a glue layer disposed on the first ESL;
a second ESL disposed on the glue layer;
a second dielectric layer over the second ESL; and
a second conductive feature extending through the second dielectric layer, the second ESL, the glue layer, and the second ESL to contact the capping layer,
wherein a density of the second ESL is greater than a density of the first ESL.

18. The semiconductor structure of claim 17, wherein the glue layer comprises aluminum nitride or silicon nitride.

19. The semiconductor structure of claim 17, wherein a dielectric constant of the second ESL is greater than a dielectric constant of the second ESL.

20. The semiconductor structure of claim 17, wherein the first ESL and the second ESL comprise silicon carbonitride.
